(19) United States
(12) Patent Application Publication
(10) Pub. No.: US 2004/0156514 A1
(43) Pub. Date: Aug. 12, 2004

(54) Control device for an audio communication system

(76) Inventors: Brian Stewart Fletcher, Macungie, PA (US); Wayne Ellsworth Wissinger, Greencastle, PA (US)

Correspondence Address: ROTHWELL, FIGG, ERNST & MANBECK, P.C., 1425 K STREET, N.W., SUITE 800, WASHINGTON, DC, 20005, US

(21) Appl. No.: 10/359,542

(22) Filed: Feb. 7, 2003

(51) Int. Cl. H04B 1/00; H03G 5/00; H03G 3/00

(52) U.S. Cl. 381/86; 381/104; 381/101

(57) ABSTRACT

A audio communication system for a vehicle includes a primary audio source producing a primary audio signal, a secondary audio source producing a secondary audio signal, a speaker, a vehicle ignition switch having an on position and an off position, and a relay. The primary and secondary audio sources may be alternatively transmissibly connected to the speaker by the relay. The relay receives the primary audio signal and transmits substantially the primary audio signal to the speaker when the vehicle ignition switch is in the on position and the secondary audio signal is not present. The relay receives the primary and secondary audio signals and transmits substantially the secondary audio signal to the speaker when the vehicle ignition switch is in the on position. The relay receives the secondary audio signal and transmits substantially the secondary audio signal to the speaker for a predetermined period of time after the vehicle ignition switch has been switched from the on position to the off position. The audio communication system may be used by receiving a primary audio signal from a primary audio source in a vehicle, driving a speaker with the primary audio signal, receiving a first secondary audio signal from a secondary audio source in the vehicle, interrupting the primary audio signal and driving the speaker with the first secondary audio signal, turning an ignition of the vehicle off, starting a predetermined period of time, receiving a second secondary audio signal from a secondary audio source within the predetermined period of time, and driving the speaker with the second secondary audio signal.

### BACKGROUND OF THE INVENTION

1. Field of the Invention

The invention relates to control of audio communication systems, and particularly to control of audio communication systems in vehicles.

2. Description of the Related Art

Drivers of over-the-road, or long-haul, trucks often have portable telephones with them while they drive. Such telephones are useful to maintain contact with friends, family members, employers and load dispatchers. Load dispatchers may need to contact a truck driver while the truck driver is on the road to direct the truck driver to a load awaiting pickup. Such a load dispatcher may contact a truck driver by calling the truck driver's portable telephone, if the telephone is on. If the telephone is not on, however, a call may be missed.

Drivers of over-the-road trucks may be away from their families for days at a time. An incoming call could be missed if, e.g. the radio or other noise in the cab was too loud, or because the engine, and consequently the portable telephone, was off. Drivers who are waiting for important news may regret missing a call, even though the call may roll over to voicemail in such instances.

Owners of truck fleets are generally interested in maximizing utilization of their trucks. Trucks are, in general, utilized fully only when they are hauling loads. Owners of truck fleets who employ drivers to drive the trucks may thus be interested in maintaining contact with the drivers while they are on the road, in order to arrange for the driver to pick up particular loads.

Independent truck drivers may be particularly interested in maintaining contact with dispatchers while they are on the road since they tend to be paid only while they are hauling a load. A trucker would desire ideally to have a load to carry at all times. Running a truck with no load costs money. An independent trucker who misses a phone call assigning a load for a return trip would thus lose money on the return trip. Independent truckers may thus feel a particular need to maintain contact with dispatchers during a drive so that loads may be arranged for the return trip.

Portable telephones may be placed in a ‘hands free’ cradle while they are in the cab. Power for the portable telephone may be drawn from the vehicle battery while the phone is in the ‘hands free’ cradle. This allows the phone to remain on, makes it easy to find the phone when a call comes in, and also obviates the need to remember to charge the battery of the portable phone.

Over-the-road, or long-haul, trucks are often equipped with sleeper cabs. Sleeper cabs allow truck drivers who are on the road for several days at a time to take breaks at appropriate times. A driver may shut the engine down during such breaks. If a call were to come in while the driver was, e.g. sleeping in a sleeper cab, the driver may not hear it. Furthermore, it may be difficult to hear the portable phone over the environmental noise of the vehicle cab while the vehicle is being driven, or if the engine is running.

These and other needs may be met by one or another of the embodiments of the invention described herein.

### SUMMARY OF THE INVENTION

In several aspects, the invention may provide a hands-free portable telephone cradle with a secondary audio amplifier in which a portable telephone may be placed. The portable telephone may drive the vehicle speakers when a call comes in, whether of not the radio is playing. If the radio is playing when a call comes in, the secondary audio amplifier may interrupt the radio so that the sound of the radio does not interfere with the call. The secondary audio amplifier may drive the vehicle speakers when a call comes in while the engine is running and for a predetermined time after the engine is shut down.

In particular, in a first embodiment an audio communication system for a vehicle includes a primary audio source producing a primary audio signal, a secondary audio source producing a secondary audio signal, a speaker, a vehicle ignition switch having an on position and an off position, and a relay. The primary and secondary audio sources may be alternatively transmissibly connected to the speaker by the relay. The relay receives the primary audio signal and transmits substantially the primary audio signal to the speaker when the vehicle ignition switch is in the on position and the secondary audio signal is not present. The relay receives the primary and secondary audio signals and transmits substantially the secondary audio signal to the speaker when the vehicle ignition switch is in the on position. The relay receives the secondary audio signal and transmits substantially the secondary audio signal to the speaker for a predetermined period of time after the vehicle ignition switch has been switched from the on position to the off position.

In a second embodiment, an audio communication system may be used by receiving a primary audio signal from a primary audio source in a vehicle, driving a speaker with the primary audio signal, receiving a first secondary audio signal from a secondary audio source in the vehicle, interrupting the primary audio signal and driving the speaker with the first secondary audio signal, turning an ignition of the vehicle off, starting a predetermined period of time, receiving a second secondary audio signal from a secondary audio source within the predetermined period of time, and driving the speaker with the second secondary audio signal.

### BRIEF DESCRIPTION OF THE SEVERAL VIEWS OF THE DRAWINGS

FIG. 1 is a schematic diagram of an audio communication system for a vehicle according to a first embodiment of the invention;

FIG. 2 is a graph of a vehicle ignition and a controlled ignition versus time for use with an embodiment of the invention;

FIG. 3 is a graph of amplifier gain correction versus time for use with an embodiment of the invention;

FIG. 4 is a vehicle for use with an embodiment of the invention; and

FIG. 5 is a vehicle ignition switch for use with an embodiment of the invention.

### DETAILED DESCRIPTION OF THE PREFERRED EMBODIMENTS

Since it may be difficult to hear a portable phone over the environmental noise of a vehicle cab if the vehicle was being driven, or if the engine was running, it may be desirable for the sound of the portable phone call to be transmitted throughout the cab on the vehicle speakers. It may also be desirable if the call were transmitted whether or not the engine was running.

Since a portable phone may be placed in a ‘hands free’ cradle in a truck cab, it can remain on in case a call comes in by drawing power from the vehicle battery. Allowing a portable phone to remain active indefinitely, however, could run the battery down eventually. It would be desirable for the call to activate the telephone only for a predetermined period of time after the ignition was shut down, to avoid discharging the battery. It would further be desirable if the driver were able to restart the predetermined period time by switching the vehicle ignition on and off. It may further be desirable to drive the speakers installed in the vehicle with audio devices other than the stereo installed in the vehicle. Finally, it may be desirable to limit the degree to which the vehicle battery is discharged through the use of such audio devices.

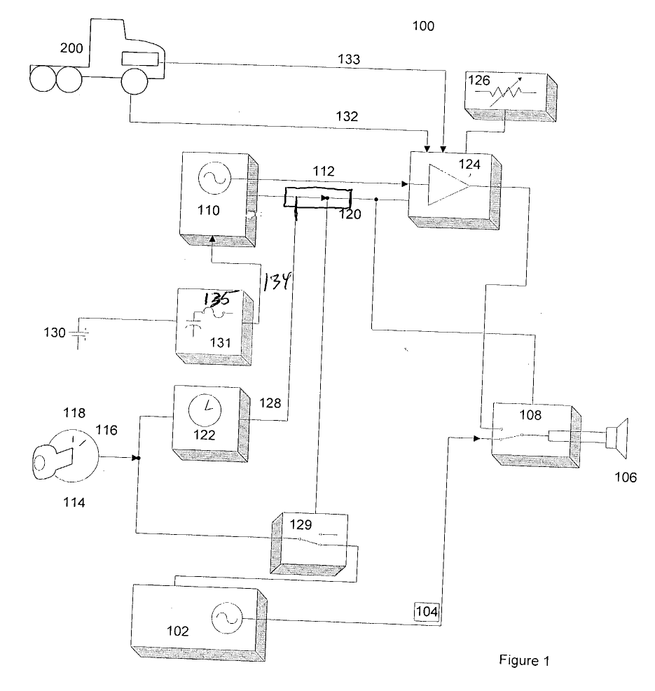

In FIG. 1 is shown an audio communication system 100 for a vehicle 200 according to a first embodiment of the invention. In FIG. 1 a primary audio source 102 produces a primary audio signal 104 which may be transmitted to a speaker 106 through a relay 108. Primary audio source 102 may be, e.g. a vehicle radio, such as an AM/FM stereo, a CD player, a handheld audio player, an MP3 player, an audio feed from a VCR, a TV, or a DVD player, a game console, or a cassette tape player. Speaker 106 may comprise, e.g. a pair of speakers, or four speakers. In one embodiment, each speaker may receive, e.g. 10 W RMS amplifier output, in order to be heard over environmental noise in a cab of vehicle 200. Relay 108 may be, e.g. a switch, such as a solenoid switch, a solid state device, such as a transistor, a vacuum tube, such as a triode, an electro mechanical switch, or a chemical switch.

A secondary audio source 110 may also produce a secondary audio signal 112 which may be transmitted to relay 108. Secondary audio source 110 may be, e.g. a portable telephone, such as a cellular phone placed in e.g. a ‘hands free’ cradle. In the alternative, secondary audio source 110 could be, e.g. a personal computer, such as a laptop or a palmtop, a personal communication device, such as a pager, a radio, such as a Citizen's Band radio, a handheld audio player, an MP3 player, an audio feed from a VCR, a TV, or a DVD player, a game console, or an alarm, such as an alarm clock. In one embodiment, secondary audio source 110 may draw power from a vehicle battery 130 when an engine of vehicle 200 is off.

Primary and secondary audio sources 102, 110 are alternatively transmissibly connected to speaker 106 by relay 108. Whether primary audio source 102 or secondary audio source 110 is connected to speaker 106 may depend on, e.g. the state of a vehicle ignition switch 114, whether a predetermined period of time has elapsed since vehicle ignition switch 114 was switched off, or whether either primary audio signal 104 or secondary audio signal 112, or both, are present.

Vehicle ignition switch 114 may have, e.g. an ‘on’ position 116 and an ‘off’ position 118. If, e.g. relay 108 receives primary audio signal 104 when vehicle ignition switch 114 is in the on position 116 and secondary audio signal 112 is not present, then relay 108 connects primary audio source 102 to speaker 106 and transmits substantially primary audio signal 104 to speaker 106.

If, in the alternative, relay 108 receives secondary audio signal 112 when vehicle ignition switch 114 is in the on position 116, relay 108 may connect secondary audio source 110 to speaker 106 and transmit substantially secondary audio signal 112 to speaker 106, whether primary audio signal 104 is present or not.

In one embodiment, if primary audio source 102 is, e.g. a CD player, a handheld audio player, such as an MP3 player, a DVD player, or cassette tape player, primary audio source 102 may be paused if primary audio source 102 is playing while relay 108 connects secondary audio source 110 to speaker 106 and transmits substantially secondary audio signal 112 to speaker 106.

In one embodiment, if e.g. speaker 106 comprises four speakers, all four may be interrupted but only two may be driven. In another embodiment, all four speakers may be interrupted and all four speakers may be driven. In one embodiment, speaker 106 has a 4 ohm impedance and a 20 W RMS capacity.

If, in a further alternative, relay 108 receives secondary audio signal 112 within a predetermined period of time after vehicle ignition switch 114 has been switched from the on position 116 to the off position 118, then relay 108 may connect secondary audio source 110 to speaker 106 and transmit substantially secondary audio signal 112 to speaker 106, whether primary audio signal 104 is present or not.

Finally, if, e.g. relay 108 receives secondary audio signal 112 after a predetermined period of time has elapsed since vehicle ignition switch 114 has been switched from the on position 116 to the off position 118, relay 108 may not transmit substantially secondary audio signal 112 to speaker 106.

Vehicle ignition switch 114 may be connected to, e.g. a timer 122 for measuring the predetermined period of time. Relay 108 may be controlled by trigger 120 responsive to secondary audio source 110. In one embodiment, timer 122 may also be operably connected to trigger 120. In another embodiment, trigger 120 may be responsive to timer 122. In still another embodiment, trigger 120 may be responsive to vehicle ignition switch 114.

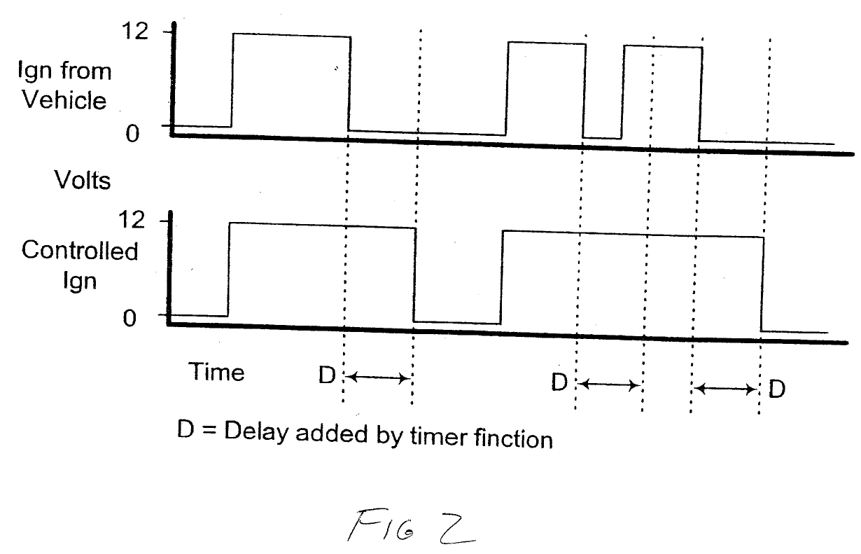

In FIG. 2 is shown a graph of vehicle ignition voltage versus time. A predetermined period of time D starts when the falling edge of the vehicle ignition passes, indicating that vehicle ignition switch 114 has been switched from the on position 116 to the off position 118. Predetermined period of time D may, e.g. re-start if vehicle ignition switch 114 is switched from the on position 116 to the off position 118 before all of predetermined period of time D has elapsed.

A controlled ignition may allow secondary audio source 110 to remain on after ignition switch 114 has been switched to off position 118. If secondary audio source 110 remains on after ignition switch 114 has been switched to off position 118, trigger 120 may activate relay 108 during predetermined period of time D if secondary audio signal 112 appears. In one embodiment, predetermined period of time D may range up to about 20 hours. In another embodiment, predetermined period of time D may range from, e.g. about 8 hours to about 15 hours. In a preferred embodiment, predetermined period of time D may be, e.g. about 15 hours.

Audio communication system 100 may have, e.g. an amplifier 124 to amplify secondary audio signal 112. In an alternative, amplifier 124 may be, e.g. a variable attenuator, such as a variable resistor. Audio communication system 100 may have, e.g. a volume control 126 operably connected to amplifier 124. Amplifier 124 may, e.g. amplify secondary audio signal 112 if secondary audio signal 112 is present and trigger 120 has activated relay 108.

Amplifier 124 may also, e.g. amplify secondary audio signal 112 for a predetermined period of time after vehicle ignition switch 114 has been switched from the on position 116 to the off position 118 when secondary audio signal 112 is present. In one embodiment, power drawn from, e.g. vehicle battery 130 by amplifier 124 may be minimal when amplifier 124 is inactive.

In one embodiment, audio communication system 100 may include, e.g. a filter 131 to suppress electrical noise 134 from vehicle 200 to audio communication system 100. Suppression of electrical noise 134 may be in the form of, e.g. passive, active, or adaptive filtering, or echo cancelling.

In one embodiment, electrical noise 134 may be filtered with a capacitor. In another embodiment, a frequency spectrum of electrical noise 134 may be, e.g. measured at some point near the audio communication system 100. The inverse or complement of the frequency spectrum of electrical noise 134 may then be, e.g. applied to the secondary audio signal 112 to remove the contribution of electrical noise 134 from secondary audio signal 112, in the manner of an echo canceller or an adaptive equalizer.

In one embodiment, audio communication system 100 may include, e.g. circuit protection for audio communication system 100. Circuit protection may be, e.g. a fuse 135 to protect a circuit of audio communication system 100 from, e.g. current or voltage surges emanating from vehicle 200.

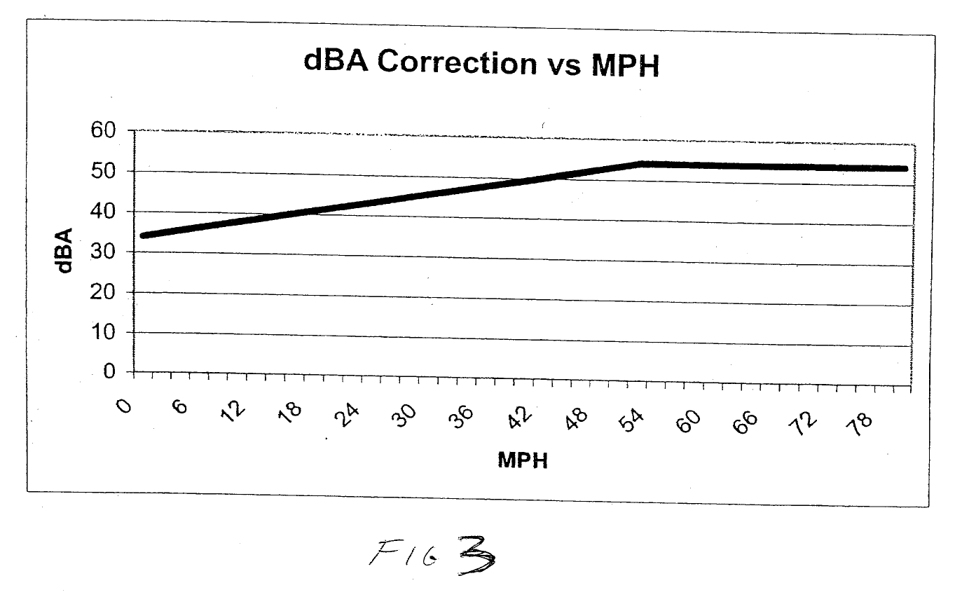

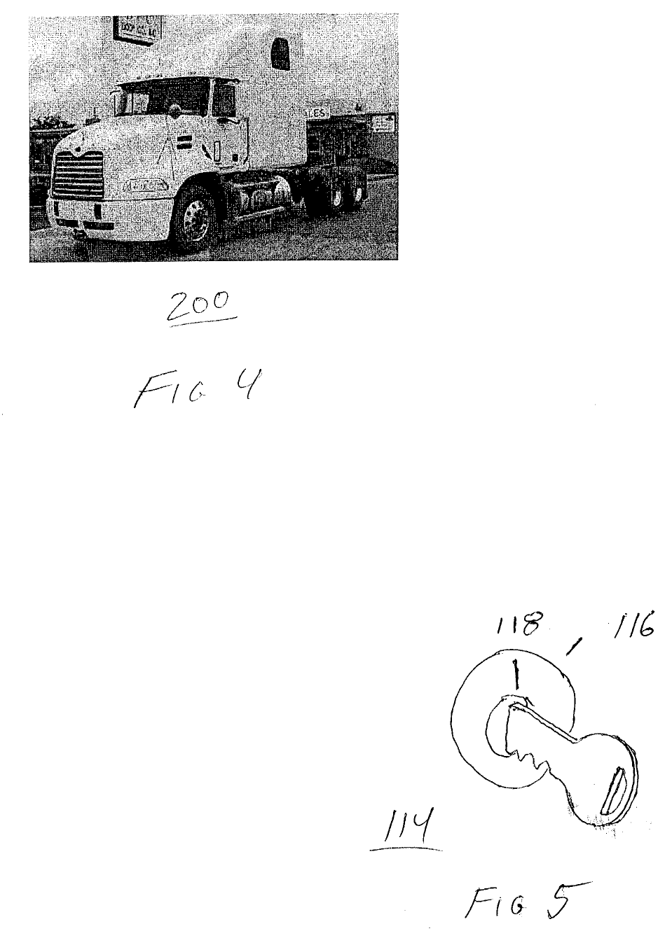

In one embodiment, a gain of amplifier 124 may increase with a signal 133 proportional to a speed of an engine of vehicle 200. In another embodiment, shown in FIG. 3, a gain of amplifier 124 may increase with a signal 132 proportional to a speed of vehicle 200. In a further embodiment, a gain of amplifier 124 may increase when an engine of vehicle 200 is started.

A gain of amplifier 124 may, e.g. be related to a speed of vehicle 200 as:

dBA=(0.387)(MPH)+34+a user adjustment,

where dBA is decibels and MPH is miles per hour.

In a preferred embodiment, noise injected by relay 108 switching may be minimized, so that no ‘thump’ is heard when amplifier 124 turns on. In another preferred embodiment, full amplification may be reached within about one second after amplifier 124 turns on.

In a second embodiment, audio communication system 100 may be used by receiving primary audio signal 104 from primary audio source 102 in vehicle 200, driving speaker 106 with primary audio signal 104, receiving a first secondary audio signal 112 from a secondary audio source 110 in vehicle 200, interrupting primary audio signal 104 and driving speaker 106 with first secondary audio signal 112, turning an ignition switch 114 of vehicle 200 off, starting a predetermined period of time, receiving a second secondary audio signal 112 from secondary audio source 110 within the predetermined period of time, and driving speaker 106 with second secondary audio signal 112.

In a third embodiment, primary audio source 102 may be paused while speaker 108 is being driven with first secondary audio signal 112.

While the invention has been described in detail above, the invention is not intended to be limited to the specific embodiments as described. It is evident that those skilled in the art may now make numerous uses and modifications of and departures from the specific embodiments described herein without departing from the inventive concepts.

What is claimed is:

1. An audio communication system for a vehicle comprising:
a primary audio source producing a primary audio signal;
a secondary audio source producing a secondary audio signal;
a speaker;
a vehicle ignition switch having an on position and an off position;
a relay, said primary and secondary audio sources alternatively transmissibly connected to said speaker by said relay;
wherein said relay receives said primary audio signal and transmits substantially said primary audio signal to said speaker when said vehicle ignition switch is in said on position and said secondary audio signal is not present;
wherein said relay receives said primary and secondary audio signals and transmits substantially said secondary audio signal to said speaker when said vehicle ignition switch is in said on position; and
wherein said relay receives said secondary audio signal and transmits substantially said secondary audio signal to said speaker for a predetermined period of time after said vehicle ignition switch has been switched from said on position to said off position.

2. The audio communication system of claim 1, comprising further a trigger responsive to said secondary audio signal, a timer, and said vehicle ignition switch to switch said relay between said primary audio signal and said secondary audio signal.

3. The audio communication system of claim 2, wherein said timer is operably connected to said trigger to control said predetermined period of time.

4. The audio communication system of claim 1, wherein said predetermined period of time is about 8 hours to about 15 hours.

5. The audio communication system of claim 1, comprising further an amplifier to amplify said secondary audio signal.

6. The audio communication system of claim 5, comprising further a volume control operably connected to said amplifier.

7. The audio communication system of claim 5, wherein said amplifier amplifies said secondary audio signal when said secondary audio signal is present and said vehicle ignition switch is in said on position.

8. The audio communication system of claim 5, wherein said amplifier amplifies said secondary audio signal when said secondary audio signal is present and for a predetermined period of time after said vehicle ignition switch has been switched from said on position to said off position.

9. The audio communication system of claim 5, wherein a gain of said amplifier increases with a speed of an engine of said vehicle.

10. The audio communication system of claim 5, wherein a gain of said amplifier increases with a speed of said vehicle.

11. The audio communication system of claim 5, wherein a gain of said amplifier increases when an engine of said vehicle is started.

12. The audio communication system of claim 1, wherein said secondary audio source is selected from the group consisting of:
a portable telephone,
a personal computer,
a laptop computer,
a palmtop computer,
a personal communication device,
a pager,
a radio,
a handheld audio player,
an MP3 player,
a VCR,
a TV,
a DVD player,
a game console,
a Citizen's Band radio, and
an alarm clock.

13. The audio communication system of claim 1, wherein said primary audio source is selected from the group consisting of:
a vehicle radio,
an AM/FM stereo,
an MP3 player,
a VCR,
a TV,
a DVD player,
a Citizen's Band radio, and
a cassette tape player.

14. The audio communication system of claim 1, comprising further electrical noise suppression.

15. The audio communication system of claim 1, comprising further circuit protection.

16. A method of using the audio communication system of claim 1 comprising the steps of:
receiving a primary audio signal from a primary audio source in a vehicle;
driving a speaker with said primary audio signal;
receiving a first secondary audio signal from a secondary audio source in said vehicle;
interrupting said primary audio signal and driving said speaker with said first secondary audio signal;
turning an ignition of said vehicle off;
starting a predetermined period of time;
receiving a second secondary audio signal from a secondary audio source within said predetermined period of time; and
driving said speaker with said second secondary audio signal.

17. A method of claim 16 comprising further the step of pausing said primary audio source while said speaker is being driven with said first secondary audio signal.

18. A vehicle having an audio communication system comprising:
a primary audio source producing a primary audio signal;
a secondary audio source producing a secondary audio signal;
a speaker in a cab of said vehicle;
a vehicle ignition switch having an on position and an off position;
a relay, said primary and secondary audio sources alternatively transmissibly connected to said speaker by said relay;
wherein said relay receives said primary audio signal and transmits substantially said primary audio signal to said speaker when said vehicle ignition switch is in said on position and said secondary audio signal is not present;
wherein said relay receives said primary and secondary audio signals and transmits substantially said secondary audio signal to said speaker when said vehicle ignition switch is in said on position; and
wherein said relay receives said secondary audio signal and transmits substantially said secondary audio signal to said speaker for a predetermined period of time after said vehicle ignition switch has been switched from said on position to said off position.
